(19) United States
(12) Patent Application Publication
(10) Pub. No.: US 2024/0395587 A1
(43) Pub. Date: Nov. 28, 2024

(54) TRANSFER SUBSTRATE AND METHOD OF MANUFACTURING ELECTRONIC APPARATUS

(71) Applicant: Japan Display Inc., Tokyo (JP)

(72) Inventors: Kenichi TAKEMASA, Tokyo (JP); Kazuyuki YAMADA, Tokyo (JP); Keisuke ASADA, Tokyo (JP); Daiki ISONO, Tokyo (JP)

(21) Appl. No.: 18/669,662

(22) Filed: May 21, 2024

(30) Foreign Application Priority Data
May 26, 2023 (JP) 2023-087200

(51) Int. Cl. H01L 21/673; H01L 23/00; H01L 25/075

(52) U.S. Cl. CPC H01L 21/67336; H01L 24/81; H01L 24/95; H01L 25/0753; H01L 2224/81224; H01L 2224/95001

(57) ABSTRACT

Performance of an electronic component including a plurality of elements is improved. A transfer substrate includes: a support substrate; an adhesive resin layer continuously provided on one surface of the support substrate and having a plurality of holding regions adhesively holding elements; and a coating film provided on a surface of the adhesive resin layer opposite to the support substrate to cover an outer region of the holding region of the adhesive resin layer and having lower surface adhesiveness than surface adhesiveness of the adhesive resin layer.

### CROSS-REFERENCE TO RELATED APPLICATION

The present application claims priority to Japanese Patent Application No. 2023-87200 filed on May 26, 2023, the disclosure of which is incorporated herein by reference.

### TECHNICAL FIELD OF THE INVENTION

The present disclosure relates to a transfer substrate and a method of manufacturing an electronic apparatus.

### BACKGROUND OF THE INVENTION

There is a method of manufacturing an electronic apparatus in which electronic components (elements) are mounted on a plurality of electrodes arranged on a circuit substrate. For example, Japanese Patent Application Laid-open Publication No. 2022-158612 (Patent Document 1) describes a method of mounting an electronic component for mounting a light-emitting element provided on a sapphire substrate on a terminal of a circuit substrate. Further, for example, Japanese Patent Application Laid-open Publication No. 2021-5632 (Patent Document 2) describes a transfer substrate including a plurality of protrusions protruding from a first surface of an elastic body as a transfer substrate for transferring a microLED element on a circuit substrate.

### SUMMARY OF THE INVENTION

As described above, an electronic apparatus may be manufactured by adhesively holding elements using an adhesive resin layer of a transfer substrate and collectively mounting the plurality of elements on a circuit substrate. When a plurality of elements are mounted on the circuit substrate as described above, for example, if the circuit substrate or the transfer substrate is warped, the transfer substrate needs to be strongly compressed against the circuit substrate. Accordingly, the adhesive resin layer may be fixed to the circuit substrate.

An objective of the present disclosure is to provide a technique of improving performance of an electronic apparatus including a plurality of elements.

A transfer substrate according to one aspect of the present disclosure includes: a support substrate; an adhesive resin layer continuously provided on one surface of the support substrate and adhesively holding elements in a plurality of holding regions, respectively; and a coating film provided on a surface of the adhesive resin layer opposite to the support substrate to cover an outer region of the holding region of the adhesive resin layer and having lower surface adhesiveness than surface adhesiveness of the adhesive resin layer.

### BRIEF DESCRIPTIONS OF THE DRAWINGS

FIG. 1 is a plan view showing an exemplary configuration of a microLED display apparatus as an embodiment of an electronic apparatus.

FIG. 2 is a circuit diagram showing an exemplary configuration of a circuit around a pixel of FIG. 1.

FIG. 3 is a transparent enlarged plan view showing an example of a structure around an LED element arranged in each of a plurality of pixels of the display apparatus of FIG. 1.

FIG. 4 is an enlarged cross-sectional view taken along a line A-A of FIG. 3.

FIG. 5 is an enlarged plan view showing a substrate structure from which the LED element of FIG. 3 is removed.

FIG. 6 is an explanatory diagram showing an example of a process flow of a method of manufacturing a display apparatus according to an embodiment of an electronic apparatus.

FIG. 7 is an enlarged cross-sectional view taken along a line B-B of FIG. 5.

FIG. 8 is a perspective view of a transfer substrate prepared in a transfer-substrate preparing step of FIG. 6.

FIG. 9 is an enlarged plan view showing a part of the transfer substrate of FIG. 8.

FIG. 10 is an enlarged cross-sectional view taken along a line C-C of FIG. 9.

FIG. 11 is a diagram for explaining an element holding step of FIG. 6.

FIG. 12 is a diagram for explaining an element compressing step of FIG. 6.

FIG. 13A is a diagram for explaining the element compressing step of FIG. 6.

FIG. 13B is a diagram for explaining the element compressing step of FIG. 6.

FIG. 13C is a diagram for explaining the element compressing step of FIG. 6.

FIG. 14 is a diagram for explaining the element compressing step of FIG. 6.

FIG. 15 is a diagram for explaining a laser emitting step of FIG. 6.

FIG. 16 is a diagram for explaining an element stripping-off step of FIG. 6.

### DESCRIPTIONS OF THE PREFERRED EMBODIMENTS

The following is explanation for each embodiment of the present invention with reference to drawings. Note that only one example is disclosed, and appropriate modification with keeping the idea of the present invention which can be anticipated by those who are skilled in the art is obviously within the scope of the present invention. Also, in order to make the explanation clear, a width, a thickness, a shape, and others of each portion in the drawings are schematically illustrated more than those in an actual aspect in some cases. However, the illustration is only an example, and does not limit the interpretation of the present invention. In the present specification and each drawing, similar elements to those described earlier for the already-described drawings are denoted with the same or similar reference characters, and detailed explanation for them is appropriately omitted in some cases.

In the following embodiments, a microLED display apparatus on which a plurality of microLED elements are mounted will be explained as an example of an electronic apparatus on which a plurality of electronic components are mounted. The microLED display apparatus may be simply referred to as a display apparatus below.

### <Electronic Apparatus>

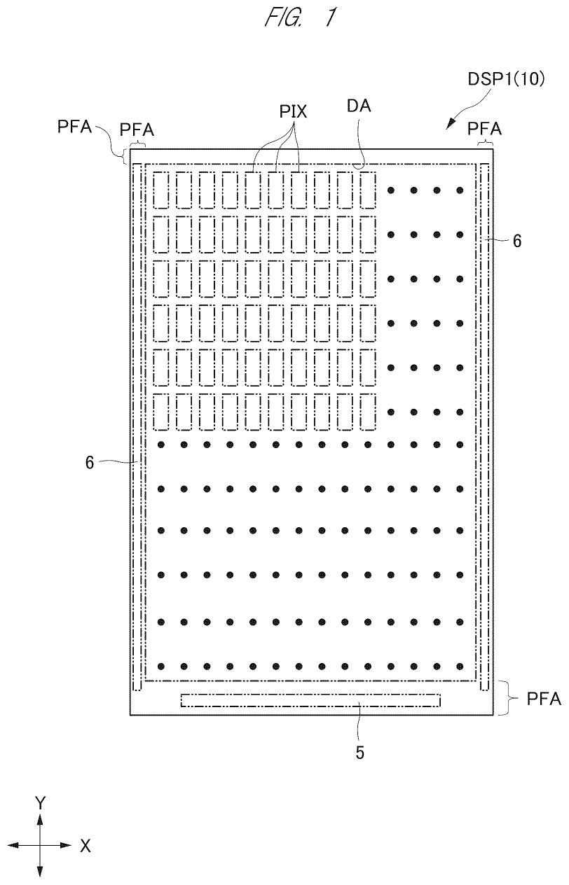

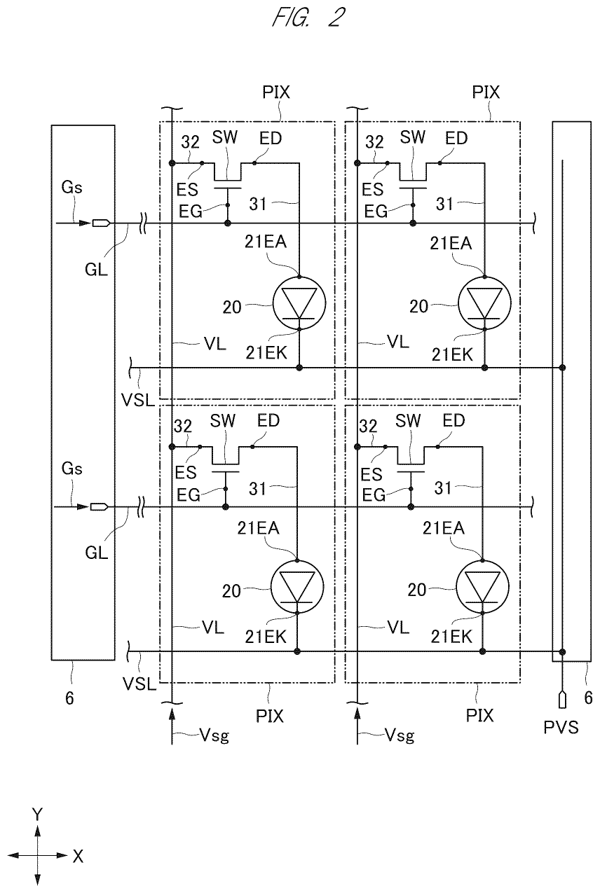

First, an exemplary configuration of a microLED display apparatus as an electronic apparatus according to the present embodiment will be described. FIG. 1 is a plan view showing the exemplary configuration of the microLED display apparatus as the embodiment of the electronic apparatus. In FIG. 1, each of a boundary between a display region DA and a peripheral region PFA, a controlling circuit 5, a driving circuit 6, and a plurality of pixels PIX is illustrated with a dashed double-dotted line. FIG. 2 is a circuit diagram showing an exemplary configuration of a circuit around a pixel of FIG. 1.

As shown in FIG. 1, a display apparatus DSP1 according to the present embodiment includes the display region DA, the peripheral region PFA surrounding the display region DA in a frame form, and a plurality of pixels PIX arranged in a matrix form inside the display region DA. The display apparatus DSP1 includes a circuit substrate 10 having a rectangular planar shape, the controlling circuit 5 formed on the circuit substrate 10, and the driving circuit 6 formed on the circuit substrate 10. The circuit substrate 10 is made of glass or resin.

The controlling circuit 5 is a circuit controlling driving of a display function of the display apparatus DSP1. The controlling circuit 5 is, for example, a driver integrated circuit (IC) mounted on the circuit substrate 10. In the example of FIG. 1, the controlling circuit 5 is arranged along one short side of four sides of the circuit substrate 10, in other words, along an X direction in the drawing. In the following explanation, the short side direction of the circuit substrate 10 may be referred to as X direction, a long side direction of the circuit substrate 10 may be referred to as Y direction, and a thickness direction of the circuit substrate 10 may be referred to as Z direction.

In the present embodiment, the controlling circuit 5 includes a signal-line driving circuit configured to drive a wiring (video signal wiring) VL (see FIG. 2) connected to the plurality of pixels PIX. However, the position and configuration of the controlling circuit 5 are not limited to those of the example of FIG. 1, and may be variously modified. For example, in FIG. 1, a wiring substrate such as flexible circuit board is connected at the position shown as the controlling circuit 5, and the driver IC may be mounted on this wiring substrate. Alternatively, for example, the signal-line driving circuit configured to drive the wiring VL may be formed separately from the controlling circuit 5.

The driving circuit 6 includes a circuit configured to drive a scan signal line GL (see FIG. 2) of the plurality of pixels PIX. The driving circuit 6 includes a circuit configured to supply a reference potential to an LED element mounted on each of the plurality of pixels PIX. The driving circuit 6 drives the plurality of scan signal lines GL on the basis of a control signal from the controlling circuit 5. In the example of FIG. 1, the driving circuit 6 is arranged along each of the long sides of the four sides of the circuit substrate 10. However, the position and exemplary configuration of the driving circuits 6 are not limited to those of the example of FIG. 1, and may be variously modified. For example, in FIG. 1, a wiring substrate such as flexible circuit board may be connected at the position shown as the controlling circuit 5, and the driving circuit 6 may be mounted on the wiring substrate.

Next, an exemplary circuit configuration of the pixels PIX will be explained with reference to FIG. 2. Note that FIG. 2 shows four pixels PIX. However, each of the plurality of pixels PIX shown in FIG. 1 includes the same circuit as those of the pixels PIX shown in FIG. 2. A circuit of the pixel PIX including a switching element SW and an LED element 20 may be referred to as a pixel circuit below. The pixel circuit is a circuit of a voltage signal system for controlling a light-emitting state of the LED element 20 in response to a video signal Vsg supplied from the controlling circuit 5 (see FIG. 1).

As shown in FIG. 2, each pixel PIX includes the LED element 20. The LED element 20 is the micro light-emitting diode. The LED element 20 includes an anode electrode 21EA and a cathode electrode 21EK. The cathode electrode 21EK of the LED element 20 is connected to a wiring VSL to which the reference potential (fixed potential) PVS is supplied. The anode electrode 21EA of the LED element 20 is electrically connected to a drain electrode ED of the switching element SW via a wiring 31.

Each pixel PIX includes the switching element SW. The switching element SW is a transistor configured to control a connection state (ON/OFF state) between the pixel circuit and the wiring VL in response to a control signal Gs. The switching element SW is, for example, a thin-film transistor. When the switching element SW is in the ON state, the video signal Vsg is input from the wiring VL into the pixel circuit.

The driving circuit 6 includes a shift register circuit, an output buffer circuit, and the like not illustrated. The driving circuit 6 outputs a pulse on the basis of a horizontal scanning start pulse transmitted from the controlling circuit 5 (see FIG. 1), and outputs the control signal Gs.

Each of the plurality of scan signal lines GL extends in the X direction. The scan signal line GL is connected to a gate electrode EG of the switching element SW. By the supply of the control signal Gs to the scan signal line GL, the switching element SW is turned ON to supply the video signal Vsg to the LED element 20.

### <Structure Around LED Element>

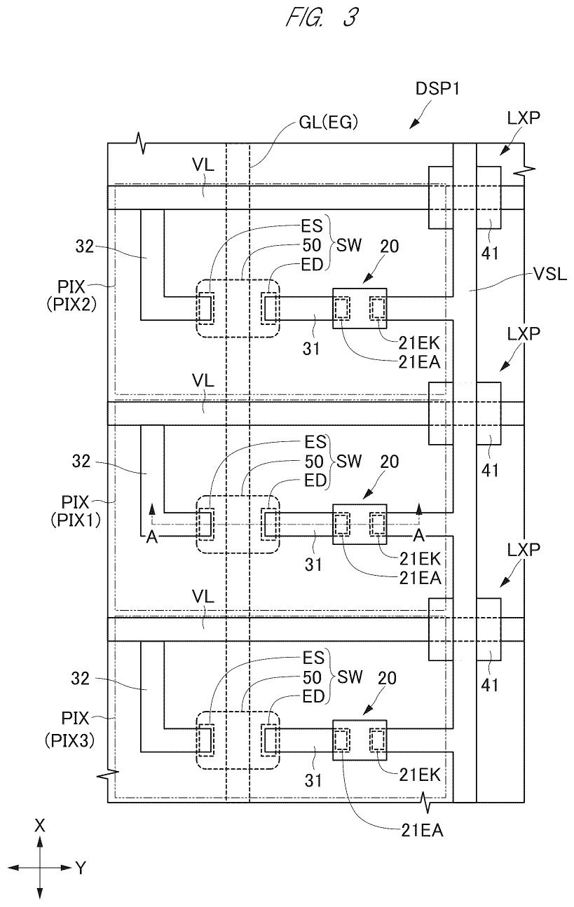

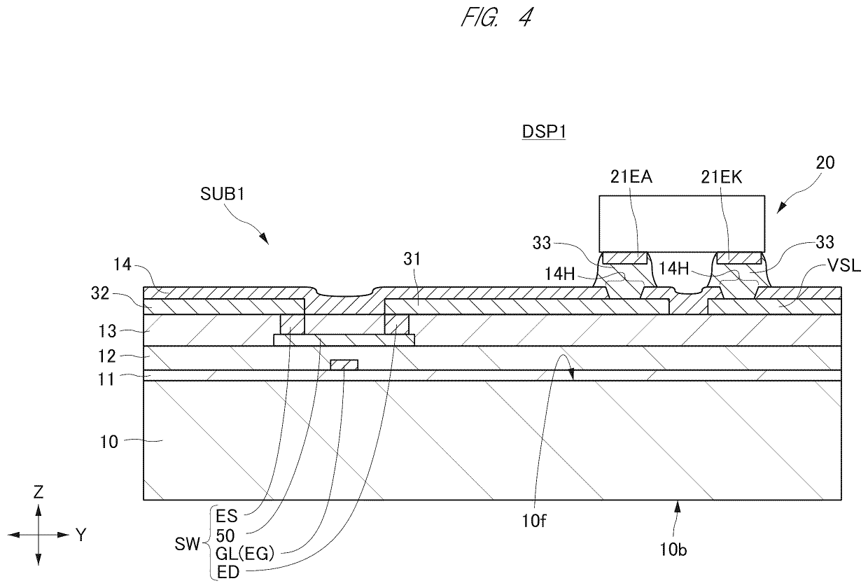

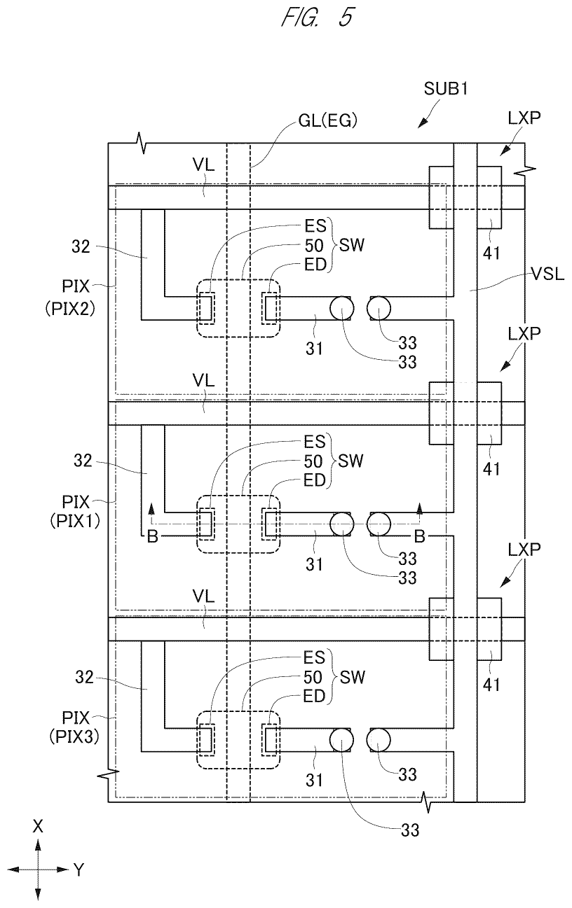

A structure around the LED element 20 arranged in each of the plurality of pixels PIX shown in FIG. 1 will be explained below. FIG. 3 is a transparent enlarged plan view showing an exemplary structure around the LED element arranged in each of the plurality of pixels of the display apparatus of FIG. 1. An inorganic insulative layer 14 shown in FIG. 4 is omitted in FIG. 3. In FIG. 3, each outline of a semiconductor layer, an electrode, and the scan signal line is illustrated with a dotted line. FIG. 4 is an enlarged cross-sectional view taken along the line A-A of FIG. 3. FIG. 5 is an enlarged plan view showing a substrate structure from which the LED element of FIG. 3 is removed.

As shown in FIG. 3, the display apparatus DSP1 includes the plurality of pixels PIX (pixels PIX1, PIX2, and PIX3 in the example of FIG. 3). Each of the pixels PIX includes the switching element SW, the LED element (light-emitting element) 20, the wiring 31, and a wiring 32. Note that the LED element 20 configured to emit a visible light of, for example, any one of red, blue, and green is mounted on each of the pixels PIX1, PIX2, and PIX3 to form the switching element SW configured to drive the LED element 20.

If the visible lights of the respective colors are emitted from the LED elements 20 of the pixels PIX1, PIX2, and PIX3, color display in the display apparatus DSP1 is achieved by controlling the outputs and timings of the visible lights emitted from the LED elements 20 of the pixels PIX1, PIX2, and PIX3. When the plurality of pixels PIX which emit the visible lights of mutually different colors are combined as described above, a pixel PIX of each color may be referred to as sub-pixel, and a set of the plurality of pixels PIX may be referred to as pixel.

The wiring 31 is electrically connected to the drain electrode ED of the switching element SW and the anode electrode 21EA of the LED element 20. The wiring 32 is connected to a source electrode ES of the switching element SW. In the example of FIG. 3, the wiring 32 has a bent structure in which one end thereof is connected to the source electrode ES of the switching element SW while the other end thereof is connected to the wiring VL. The scan signal line GL is used as the gate electrode EG of the switching element SW.

The display apparatus DSP1 further includes the wiring VL and a wiring VSL. The wiring VL extends over the plurality of pixels (see FIG. 2) along the Y direction, and is electrically connected to the wirings 32. The wiring VSL extends over the plurality of pixels PIX along the X direction crossing (in FIG. 3, orthogonal to) the Y direction, and is electrically connected to the cathode electrodes 21EK of the LED elements 20. The wiring VL and the wiring VSL cross with each other via an insulative layer 41 at a wiring crossing portion LXP shown in FIG. 3. The insulative layer 41 interposes between the wiring VL and the wiring VSL, and thus, the wiring VL and the wiring VSL are electrically isolated from each other.

As shown in FIG. 4, the display apparatus DSP1 is an electronic apparatus including the LED elements 20 and a substrate structure SUB1. The substrate structure SUB1 is configured to include the circuit substrate 10 made of glass or resin and a plurality of insulative layers stacked on the circuit substrate 10. The plurality of insulative layers of the substrate structure SUB1 include an inorganic insulative layer 11, an inorganic insulative layer 12, an inorganic insulative layer 13, and the inorganic insulative layer 14 which are stacked on the circuit substrate 10. The circuit substrate 10 has a surface 10f and a surface 10b opposite to the surface 10f. The inorganic insulative layers 11, 12, 13, and 14 are stacked on the surface 10f of the circuit substrate 10.

The switching element SW includes the inorganic insulative layer 12 formed on the circuit substrate 10, a semiconductor layer 50 formed on the inorganic insulative layer 12, the drain electrode ED connected to a drain region of the semiconductor layer 50, the source electrode ES connected to a source region of the semiconductor layer 50, and the inorganic insulative layer 13 covering the semiconductor layer 50. Each of the wiring 31 and the wiring 32 is a stacked film of, for example, a conductor layer made of titanium or a titanium alloy and a conductor layer made of aluminum or an aluminum alloy. The stacked film including the titanium layers sandwiching the aluminum layer therebetween is referred to as a TAT stacked film.

The example of FIG. 4 is an example of a bottom-gate system which the gate electrode EG interposes between the semiconductor layer 50 and the circuit substrate 10. In the bottom-gate system, a part of the inorganic insulative layer 12 between the gate electrode EG and the semiconductor layer 50 functions as a gate insulative layer. The inorganic insulative layer 12 also functions as a base layer for forming the semiconductor layer 50. Note that a position of the gate electrode EG is not limited to that of the example of FIG. 4, and, for example, a top-gate system may be applied.

Although a material making each of the inorganic insulative layers 11, 12, 13, and 14 is not particularly limited, for example, silicon oxide (SiO), silicon nitride (SiN), or the like is exemplified. The semiconductor layer 50 is a semiconductor film that is a silicon film made of silicon doped with a P-type or N-type conductive impurity.

Each of the source electrode ES and the drain electrode ED is a contact plug for making electric contact with either one of the source region and the drain region of the semiconductor layer 50. As a material of the contact plug, for example, tungsten or the like is exemplified. As a modification example of FIG. 4, a contact hole for exposing the source region and the drain region of the semiconductor layer 50 may be formed in the inorganic insulative layer 13, and each of a part of the wiring 31 and a part of the wiring 32 may be embedded in the contact hole. In this case, the embedded parts of the wiring 31 and the wiring 32 in the contact holes come into contact with the semiconductor layer 50, and the contact interfaces between the wirings 31, 32 and the semiconductor layer 50 can be regarded as the drain electrode ED and the source electrode ES.

As shown in FIG. 5, the substrate structure SUB1 includes a plurality of bump electrodes 33 orderly arranged in plan view. The bump electrode 33 is a terminal for mounting the electronic component on the circuit substrate 10 (see FIG. 4). In the present embodiment, the bump electrode 33 is a terminal for mounting the LED element 20 shown in FIG. 4. Thus, two bump electrodes 33 are adjacently arranged in a region where the LED element 20 (see FIG. 3) is to be mounted. One of the two bump electrodes 33 is connected to the anode electrode 21EA of the LED element 20, and the other is connected to the cathode electrode 21EK of the LED element 20.

As shown in FIG. 4, the bump electrode 33 is connected to the wiring 31 at a position overlapping an opening 14H formed in the inorganic insulative layer 14, and protrudes from the inorganic insulative layer 14. The bump electrode 33 is made of, for example, solder containing tin. Alternatively, the bump electrode 33 may be a stacking body made of a metal layer made of a metallic material such as copper having higher electric conductivity than solder and a solder layer.

### <Method of Manufacturing Electronic Apparatus>

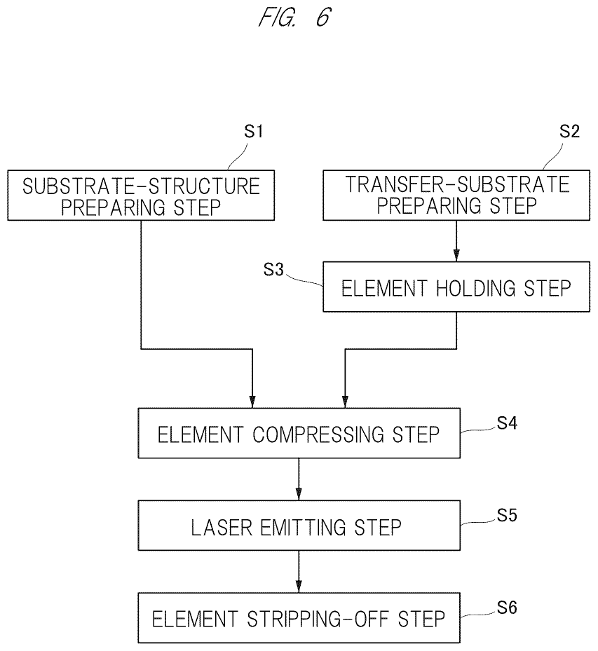

Next, a method of manufacturing an electronic apparatus according to the present embodiment will be explained as a representative example of the method of manufacturing the display apparatus DSP1 of FIG. 3. FIG. 6 is an explanatory diagram showing an example of a process flow of the method of manufacturing the display apparatus as an embodiment of the electronic apparatus.

As shown in FIG. 6, the method of manufacturing the electronic apparatus according to the present embodiment includes a substrate-structure preparing step S1, a transfer-substrate preparing step S2, an element holding step S3, an element compressing step S4, a laser emitting step S5, and an element stripping-off step S6.

### <Substrate-Structure Preparing Step>

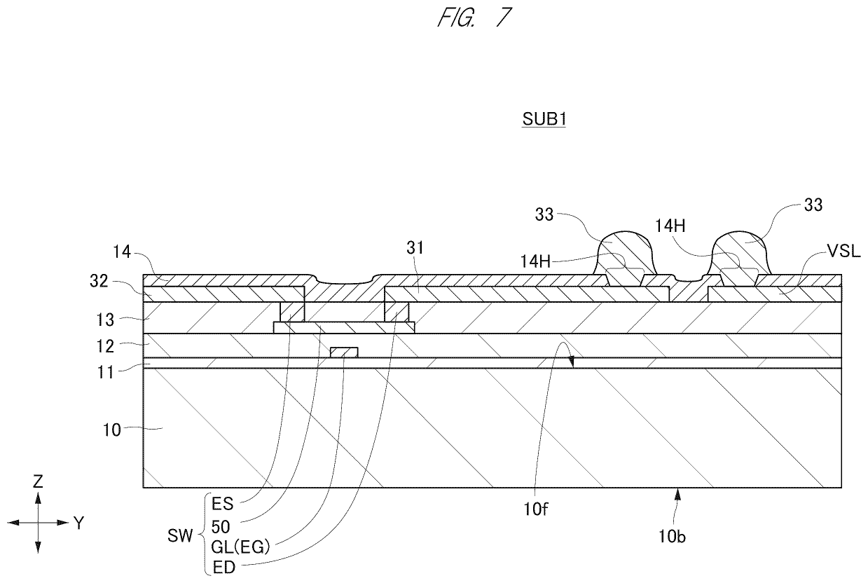

The substrate structure SUB1 of FIG. 7 is prepared in the substrate-structure preparing step S1 of FIG. 6. FIG. 7 is a diagram for explaining the substrate-structure preparing step, and is an enlarged cross-sectional view of the substrate structure taken along the line B-B of FIG. 5. In the substrate-structure preparing step S1, as shown in FIG. 7, the substrate structure SUB1 including the circuit substrate 10 made of glass or resin, the wiring 31 formed on the circuit substrate 10, and the inorganic insulative layer 14 covering the wiring 31 is prepared. The inorganic insulative layer 11, the inorganic insulative layer 12, the inorganic insulative layer 13, and the inorganic insulative layer 14 are stacked on the circuit substrate 10, and the wiring 31 is arranged between the inorganic insulative layer 13 and the inorganic insulative layer 14. Most of the substrate structure SUB1 is covered with the inorganic insulative layer 14. The opening 14H is formed in the inorganic insulative layer 14 at a position overlapping the wiring 31 and a position overlapping the wiring VSL. The wiring 31 and the wiring VSL are exposed from the inorganic insulative layer 14 at the bottoms of the openings 14H.

Each of the plurality of bump electrodes 33 is embedded in the opening 14H and is connected to the wiring 31 or the wiring VSL at the bottom of the opening 14H. As shown in FIG. 5, in plan view of the substrate structure SUB1, the plurality of bump electrodes 33 are orderly arranged in the region where the electronic component (LED element 20 of FIG. 3) are to be mounted.

As shown in FIG. 7, the bump electrode 33 is formed to protrude above the inorganic insulative layer 14. As described above, a part of the wiring 31 and a part of the wiring VSL are partially exposed from the inorganic insulative layer 14 at the openings 14H, and thus, the bump electrode 33 can be selectively formed by, for example, an electroplating method. Note that the bump electrode 33 may be formed under use of a resist film in order to increase a height of the protrusion of the bump electrode 33.

### <Transfer-Substrate Preparing Step>

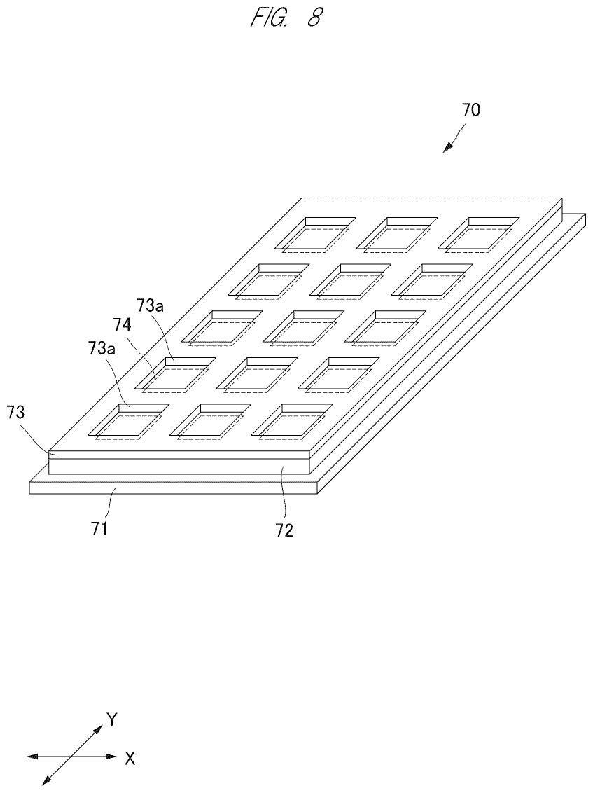

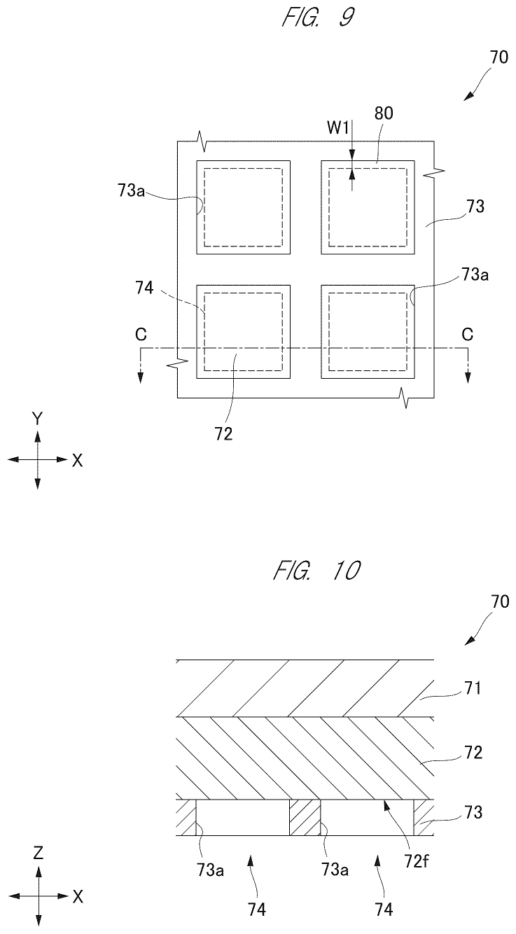

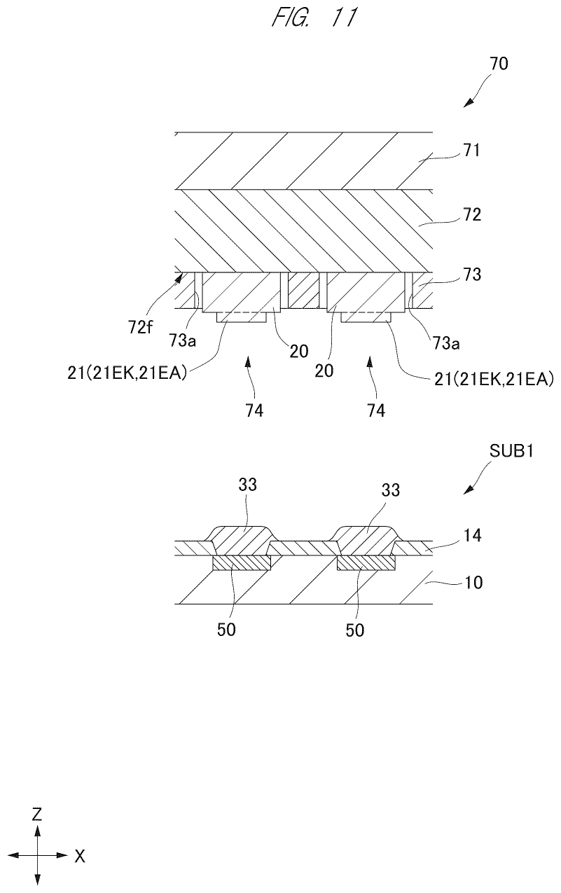

In the transfer-substrate preparing step S2 of FIG. 6, a transfer substrate shown in FIGS. 8 to 10 is prepared. FIG. 8 is a perspective view of the transfer substrate prepared in the transfer-substrate preparing step. FIG. 9 is an enlarged plan view showing a part of the transfer substrate, and FIG. 10 is an enlarged cross-sectional view taken along the line C-C of FIG. 9.

The transfer substrate 70 shown in FIGS. 8 to 10 includes a support substrate 71, an adhesive resin layer 72 provided on either one surface of the support substrate 71, and a coating film 73 provided on a surface of the adhesive resin layer 72 opposite to the support substrate 71. The support substrate 71 is a substrate having a substantially rectangular planar shape used for ensuring rigidity of the transfer substrate 70. The support substrate 71 is a synthetic substrate containing, for example, silicon oxide such as quartz or glass, as a main component. Note that the substrate having the rectangular planar shape is exemplified as the transfer substrate 70. However, this is one example, and the shape of the transfer substrate 70 is not particularly limited.

The adhesive resin layer 72 is a layer used for adhesively holding the plurality of LED elements 20 in the element holding step S3 described below, and is continuously provided on the surface of the support substrate 71. More specifically, the adhesive resin layer 72 (the transfer substrate 70) has a plurality of holding regions 74 in a matrix form adhesively holding the LED elements 20. The adhesive resin layer 72 is provided on the support substrate 71 in a range including these holding regions 74.

Note that the number of the holding regions 74 of the adhesive resin layer 72 (the transfer substrate 70) is not particularly limited. The number of the holding regions 74 may be appropriately determined depending on, for example, the number of the LED elements 20 of the display apparatus DSP1.

The adhesive resin layer 72 is made of a resin material having adhesiveness capable of adhesively holding the LED elements 20, and a surface 72f (see FIG. 10) thereof opposite to the support substrate 71 has adhesiveness capable of adhesively holding the LED elements 20. However, the LED elements 20 adhesively held by the adhesive resin layer 72 are stripped off from the adhesive resin layer 72 after being mounted on the substrate structure SUB1. Thus, the adhesiveness of the adhesive resin layer 72 needs to be appropriately adjusted in consideration of this point. A thickness of the adhesive resin layer 72 is not particularly limited, but preferably about several tens μm, and is about 20 μm in the present embodiment.

As a resin material of the adhesive resin layer 72, for example, acrylic resin, polyester-based resin, vinyl chloride-vinyl acetate copolymer resin, ethylene-acrylic ester copolymer resin, ethylene-methacrylic ester copolymer resin, polyamide-based resin, polyolefin-based resin, chlorinated polyolefin-based resin, epoxy-based resin, urethane-based resin, or the like is exemplified. Obviously, the resin materials for the adhesive resin layer 72 are not limited thereto.

The coating film 73 is a film used for suppressing adhesion of the adhesive resin layer 72 to the substrate structure SUB1 including the circuit substrate 10 in the element compressing step S4 described below, and the adhesiveness of the surface adhesiveness the coating film 73 is lower than the adhesiveness of the surface of the adhesive resin layer 72. In other words, the coating film 73 is made of a material having lower adhesiveness than that of the resin material of the adhesive resin layer 72. As described above, the adhesive resin layer 72 has the surface 72f having the adhesiveness capable of adhering the LED elements 20. As a result, the adhesive resin layer 72 has the surface 72f having the adhesiveness adhering to the substrate structure SUB1. The adhesiveness of the surface of the coating film 73 is lower than the adhesiveness of the surface 72f of the adhesive resin layer 72.

The adhesiveness of the surface of coating film 73 preferably has the remarkably low, and particularly the surface preferably has no surface adhesiveness. That is, A type of the coating film 73 having the lower surface adhesiveness than that of the adhesive resin layer 72 includes not only a type having the lower surface adhesiveness but also a type having no surface adhesiveness.

The coating film 73 is provided on one surface of the adhesive resin layer 72, that is the surface 72f of the adhesive resin layer 72 opposite to the support substrate 71 in this example. The coating film 73 is provided to cover an outer region of the holding region 74 in the surface 72f of the adhesive resin layer 72. As an example, the coating film 73 is provided to surround a periphery of each holding region 74. In other words, the coating film 73 is provided over the substantially entire surface 72f of the adhesive resin layer 72 except for a part corresponding to each holding region 74. In another words, the coating film 73 is provided over the substantially entire surface 72f of the adhesive resin layer 72, and includes an opening 73a at a position corresponding to each holding region 74.

An opening shape (planar shape) of the opening 73a is not particularly limited, but preferably an opening shape formed along the planar shape of the holding region 74. Each holding region 74 is a region adhesively holding the LED element 20. As an example, the shape of the holding region 74 coincides with the planar shape of the LED element 20. Thus, it can be also said that the shape of the opening 73a preferably has the shape formed along the planar shape of the LED element 20. In the present embodiment, the planar shape of the LED element 20 is rectangular, and thus, the shape of each holding region 74 is also rectangular. Therefore, the opening shape of the opening 73a is preferably also rectangular along the shape of the holding region 74.

The opening 73a of the coating film 73 is preferably slightly larger than each holding region 74 in consideration of positioning accuracy provided when the LED element 20 is adhesively held by the adhesive resin layer 72. For example, when the shape of the LED element 20 (the shape of the holding region 74) is a rectangular shape of about 20 to 30 μm square, a length of one side of the opening 73a is about 2 to 5 μm larger than a length of one side of the holding region 74. In other words, for example, as shown in FIG. 9, a gap 80 having a predetermined width W1 of about 1 to 2.5 μm preferably exists between the periphery of the holding region 74 and the adhesive resin layer 72.

The coating film 73 is made of, for example, a metallic thin film such as copper or aluminum. However, the material of the coating film 73 is not limited to such a metallic material. As the material of the coating film 73, an inorganic material is preferably used. However, any material capable of suppressing the adhesion of the adhesive resin layer 72 to the substrate structure SUB1 and being endurable to heat applied in the laser emitting step described below is applicable. The material of the coating film 73 is preferably a material not adhesive to the substrate structure SUB1, particularly a material not having the adhesiveness thereto.

A method of forming the coting film 73 made of the metallic thin film is not particularly limited. However, for example, a vapor deposition method, a sputtering method, or the like is exemplified. For example, the coating film 73 may be formed by forming the metallic thin film on a different substrate from the transfer substrate 70 and then transferring this metallic thin film onto the adhesive resin layer 72.

### <Element Holding Step>

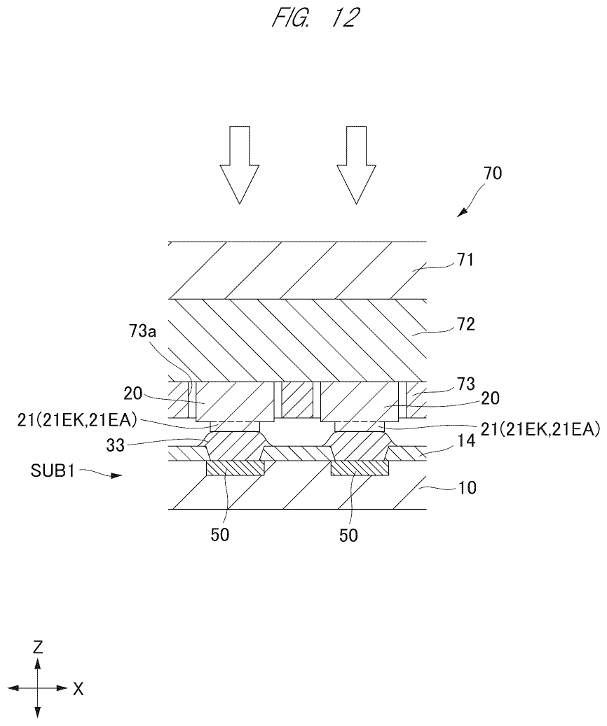

Next, in the element holding step S3 of FIG. 6, as shown in FIG. 11, the LED element 20 is adhesively held in each of the plurality of holding regions 74 of the transfer substrate 70 by the adhesive resin layer 72. FIG. 11 is a diagram for explaining the element holding step. More specifically, FIG. 11 is an enlarged cross-sectional view showing a state in which the LED element is held in each holding region of the transfer substrate of FIG. 10 by the adhesive resin layer.

In this step, by making the contact of the plurality of LED elements 20 with the adhesive resin layer 72 of the transfer substrate 70, the plurality of LED elements 20 are adhesively held by the transfer substrate 70. Specifically, the surface of the LED element 20 opposite to its surface where the electrodes 21 (the anode electrode 21EA and the cathode electrode 21EK) are formed is adhesively held by one surface 72f of the adhesive resin layer 72. In other words, the LED element 20 is adhesively held by the transfer substrate 70 such that its surface where the anode electrode 21EA and the cathode electrode 21EK are formed faces the substrate structure SUB1. Note that the anode electrode 21EA and the cathode electrode 21EK of the LED element 20 may be collectively referred to as electrodes 21.

Each of the LED elements 20 adhesively held by the transfer substrate 70 as described above is first formed on, for example, a sapphire substrate. Each of the plurality of LED elements 20 completed on the sapphire substrate is temporarily transferred onto a first transfer substrate, and then, is transferred from the first transfer substrate to the transfer substrate 70. FIG. 11 shows a state provided after the plurality of LED elements 20 are transferred from the first transfer substrate to the transfer substrate 70. Since each of the plurality of LED elements 20 formed on the sapphire substrate is transferred through the first transfer substrate to the transfer substrate 70, the LED elements 20 are held by the transfer substrate 70 while the electrode 21 faces the substrate structure SUB1.

### <Element Compressing Step>

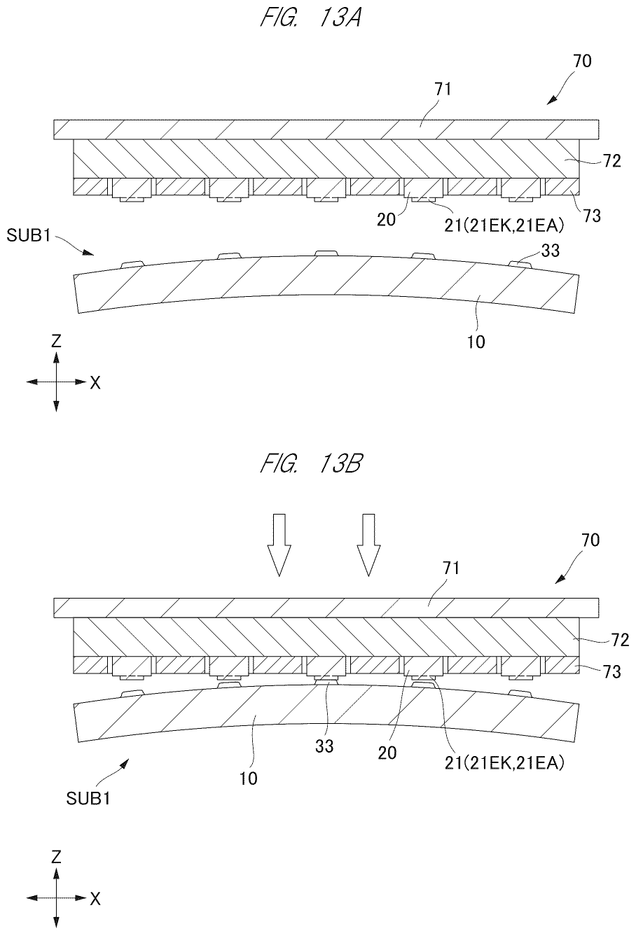

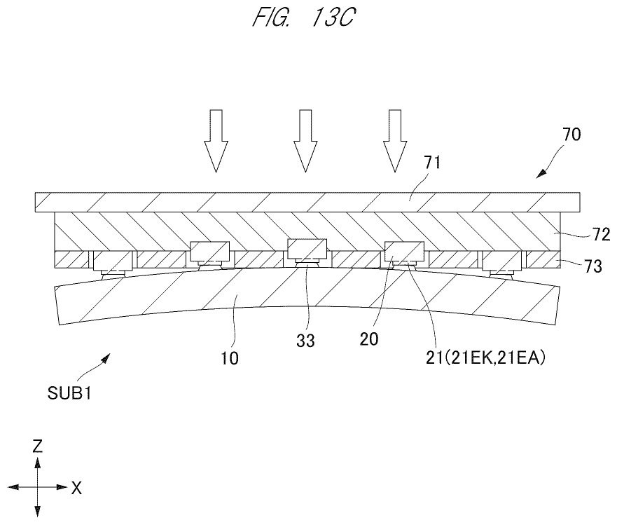

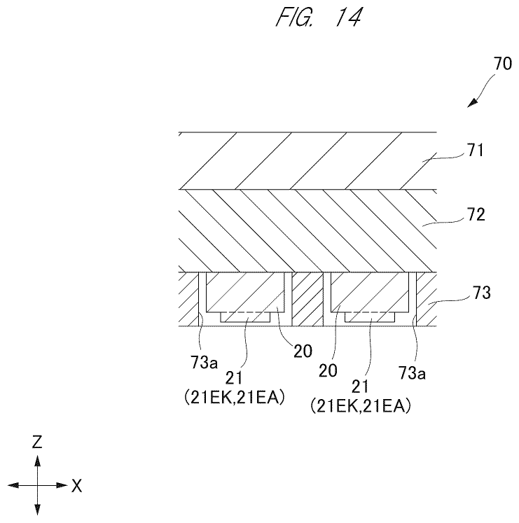

Next, in the element compressing step S4 of FIG. 6, as shown in FIG. 12, the transfer substrate 70 adhesively holding the plurality of LED elements 20 is compressed against the substrate structure SUB1 prepared in the substrate-structure preparing step S1. FIGS. 12 and 13A to 13C are diagrams for explaining the element compressing step. More specifically, FIG. 12 is an enlarged cross-sectional view showing a state in which the transfer substrate is compressed against the substrate structure in the element compressing step. FIGS. 13A to 13C are schematic diagrams for explaining the element compressing step provided when the substrate structure SUB1 is warped. FIG. 14 is a cross-sectional view for explaining a modification example of the transfer substrate.

In this step, the transfer substrate 70 is compressed against the substrate structure SUB1 in a state in which the electrodes 21 of the LED elements 20 adhesively held by the plurality of holding regions 74 of the adhesive resin layer 72 of the transfer substrate 70 face the plurality of bump electrodes 33 formed the on substrate structure SUB1, respectively. In the manner, the electrodes 21 of the plurality of LED elements 20 held by the transfer substrate 70 come into contact with the plurality of bump electrodes 33, respectively.

Here, it is assumed that, for example, the circuit substrate 10 configuring the substrate structure SUB1 is warped. In this case, in order to make the contact of the electrodes 21 of the plurality of LED elements 20 with the corresponding bump electrodes 33, the transfer substrate 70 needs to be more strongly compressed against the substrate structure SUB1 than that in no warpage case of the circuit substrate 10. Accordingly, there is a risk of adhesion of the adhesive resin layer 72 to the substrate structure SUB1 including the circuit substrate 10. However, since the coating film 73 is provided on the surface of the adhesive resin layer 72 configuring the transfer substrate 70, the adhesion of the adhesive resin layer 72 to the substrate structure SUB1 can be suppressed.

Specifically, for example, as shown in FIG. 13A, it is assumed that the substrate structure SUB1 is warped to protrude toward the transfer substrate 70 so that the warpage of the center of the substrate structure SUB1 in the X direction is the largest. In this case, when the transfer substrate 70 is compressed against the substrate structure SUB1, the electrode 21 of the LED element 20 comes into contact with the bump electrode 33 firstly at the center of the substrate structure SUB1 in the X direction having the largest warpage as shown in FIG. 13B. To the contrary, at both ends of the substrate structure SUB1 in the X direction, the electrodes 21 of the LED elements 20 do not come into contact with the bump electrodes 33.

In order to make the contact of all the electrodes 21 of the LED elements 20 with the bump electrodes 33, the transfer substrate 70 needs to be more strongly compressed against the substrate structure SUB1. In the manner, as shown in FIG. 13C, all the electrodes 21 of the LED elements 20 can come into contact with the bump electrodes 33 of the substrate structure SUB1. However, for example, at the center of the substrate structure SUB1 in the X direction, the adhesive resin layer 72 is squashed by the LED element 20. In other words, the LED element 20 is compressed into the adhesive resin layer 72.

If an area of the substrate structure SUB1 is relatively small, a warpage amount is suppressed to be relatively small, and thus, the LED element 20 is difficult to be compressed into the adhesive resin layer 72. To the contrary, if the area of the substrate structure SUB1 is relatively large, the warpage amount tends to be large. Accordingly, the LED element 20 tends to be compressed into the adhesive resin layer 72. Since the LED element 20 is compressed into the adhesive resin layer 72 as described above, the adhesive resin layer 72 tends to adhere to the surface of the substrate structure SUB1.

However, the coating film 73 is provided on the surface of the adhesive resin layer 72, the adhesion of the adhesive resin layer 72 to the substrate structure SUB1 can be suppressed. More specifically, even when the LED element 20 is compressed into the adhesive resin layer 72, the coating film 73 exists between the adhesive resin layer 72 and the substrate structure SUB1. Thus, the adhesive resin layer 72 does not directly come into contact with the surface of the substrate structure SUB1. Therefore, the adhesion of the adhesive resin layer 72 to the substrate structure SUB1 can be suppressed.

Particularly, if the thickness of the adhesive resin layer 72 is larger than the height of the LED element 20, when the LED element 20 is compressed into the adhesive resin layer 72, the adhesive resin layer 72 tends to adhere to the substrate structure SUB1. Even in this case, since the coating film 73 is provided on the surface of the adhesive resin layer 72, the adhesion of the adhesive resin layer 72 to the substrate structure SUB1 can be effectively suppressed.

If the adhesive resin layer 72 is compressed by the LED element 20, the surface of the substrate structure SUB1 may come into contact with the coating film 73. In this case, the adhesive resin layer 72 is also pressurized by the coating film 73. However, the coating film 73 is continuously formed in the outer region of the holding region 74 of the transfer substrate 70, and its area is relatively large. More specifically, the contact area of the coating film 73 with the adhesive resin layer 72 is larger than the contact area of each LED element 20 with the adhesive resin layer 72. Thus, the coating film 73 is more difficult to be compressed into the adhesive resin layer 72 than the LED element 20.

The thickness of the coating film 73 is not particularly limited but is preferably smaller than the height of the LED element 20. In other words, when the LED element 20 is adhesively held by the adhesive resin layer 72, the tip of the LED element 20 is preferably positioned at an outer region of the surface of the coating film 73 in the Z direction. In the manner, in the element holding step S3, the LED element 20 is easily adhesively held onto the adhesive resin layer 72 of the transfer substrate 70.

To the contrary, in order to suppress the adhesion of the adhesive resin layer 72 to the substrate structure SUB1, for example, the thickness of the coating film 73 is preferably larger than the height of the LED element 20 as shown in FIG. 14. Additionally, the thickness of the coating film 73 is preferably the same as or slightly larger than a total of the height of the LED element 20 and a height of the bump electrode 33 of the substrate structure SUB1.

In the manner, even if the LED element 20 is compressed into the adhesive resin layer 72, a sufficient gap can be ensured between the adhesive resin layer 72 and the substrate structure SUB1. In the manner, the adhesion of the adhesive resin layer 72 to the substrate structure SUB1 can be securely suppressed. The sufficient gap is ensured between the adhesive resin layer 72 and the substrate structure SUB1. Therefore, the adhesion of the adhesive resin layer 72 to the substrate structure SUB1 through the gap between the LED element 20 and the coating film 73 provided when, for example, the LED element 20 is compressed into the adhesive resin layer 72, is suppressed.

When the thickness of the coating film 73 is made larger than the height of the LED element 20, in the element holding step S3, the LED element 20 is difficult to be adhesively held by the adhesive resin layer 72 of the transfer substrate 70. However, by, for example, devisal for the shape of the first transfer substrate, the LED element 20 held on the first transfer substrate can be easily adhesively held onto the adhesive resin layer 72 of the transfer substrate 70. As an example, a portion of the first transfer substrate, the portion facing the holding region 74, may be provided with a protrusion having a smaller area than that of the holding region 74 so that the LED element 20 is held on this protrusion.

The explanation for the present embodiment has been made in the case in which the substrate structure SUB1 is warped to be the curved surface centering the side opposite to the transfer substrate 70 so that the warpage of the center of the substrate structure SUB1 in the X direction is the largest. However, the state of the warpage is not limited to this example. For example, even if the substrate structure SUB1 is warped to be a curved surface centering the side of the transfer substrate 70, the similar effects can be achieved. Further, even if the transfer substrate 70 is warped as described above, the similar effects can be achieved.

### <Laser Emitting Step>

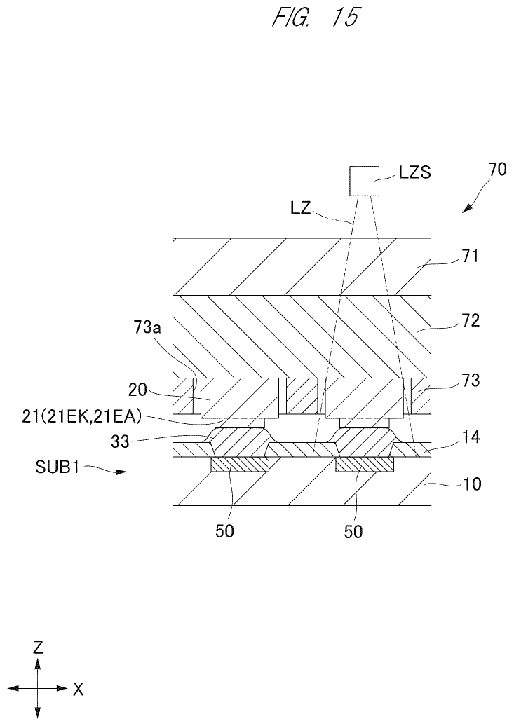

Next, in the laser emitting step S5 of FIG. 6, as shown in FIG. 15, laser LZ is emitted from a laser source LZS to the plurality of bump electrodes 33 and a plurality of contact parts between the bump electrodes 33 and the electrodes 21 of the plurality of LED elements 20. In the manner, the electrode 21 of each LED element 20 is bonded to the bump electrode 33. FIG. 15 is a diagram for explaining the laser emitting step. More specifically, FIG. 15 is an enlarged cross-sectional view schematically showing a state in which the laser is emitted to the contact part between the electrode 21 of the LED element 20 and the bump electrode 33.

In this step, since the laser LZ is emitted to the contact part between the bump electrode 33 and the electrode 21 of each LED element 20, the contact part is heated. More specifically, the heat is applied to the bump electrode 33, solder contained in the bump electrode 33 is melted, and the bump electrode 33 is bonded to the electrode 21 of each LED element 20 by the solder.

Note that a step of previously forming a solder film on the anode electrode 21EA and the cathode electrode 21EK of the LED element 20 may be performed prior to this step. The solder-containing bump electrode 33 can be easily unified with the solder film formed on the anode electrode 21EA and the cathode electrode 21EK. Thus, by the formation of the solder film on each of the anode electrode 21EA and the cathode electrode 21EK, the bump electrode 33 and each electrode 21 of the LED element 20 can be made easier to be bond in this step.

### <Element Stripping-Off Step>

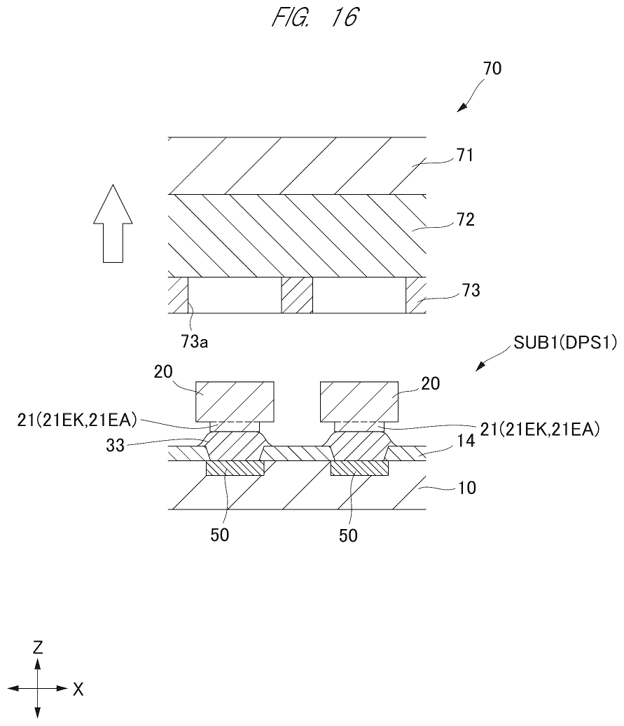

Next, in the element stripping-off step S6 of FIG. 6, as shown in FIG. 16, the plurality of LED elements 20 are stripped off from the adhesive resin layer 72 of the transfer substrate 70. FIG. 16 is a diagram for explaining the element stripping-off step. More specifically, FIG. 16 is an enlarged cross-sectional view showing a state in which the adhesive resin layer 72 of the transfer substrate 70 is stripped off from the plurality of LED elements 20.

In this step, the transfer substrate 70 is moved in the Z direction to separate the transfer substrate 70 from the substrate structure SUB1. At this time, the electrodes 21 of the plurality of LED elements 20 are bonded to the bump electrodes 33 of the substrate structure SUB1. In other words, the plurality of LED elements 20 are mounted on the substrate structure SUB1, and the fixing strength between the electrodes 21 of the LED elements 20 and the bump electrodes 33 is higher than the adhesive strength between each LED element 20 and the adhesive resin layer 72. Thus, since the transfer substrate 70 is moved to separate from the substrate structure SUB1, the interface between the adhesive resin layer 72 and the LED element 20 is stripped off. This step provides the display apparatus DPS1 in which the plurality of LED elements 20 are mounted on the substrate structure SUB1.

As described above, in the transfer substrate 70 according to the present disclosure, the coating film 73 having the lower surface adhesiveness than that of the adhesive resin layer 72 is provided on the side of the adhesive resin layer 72 opposite to the support substrate 71 so as to cover the outer region of the holding region 74 of the adhesive resin layer 72. In the manner, the fixed adhesion of the adhesive resin layer 72 to the substrate structure SUB1 can be suppressed.

As described above, in the element compressing step S4, there is a risk of adhesion of a part of the adhesive resin layer 72 to the surface of the substrate structure SUB1. In the laser emitting step S5 in this state, the emission of the laser LZ causes a risk of fixation of a part (adhesive resin) of the adhesive resin layer 72 having been adhered on the substrate structure SUB1 onto the substrate structure SUB1.

More specifically, in the laser emitting step S5, when the heat is applied to the bump electrode 33, the temperature of the substrate structure SUB1 also increases. Thus, if the adhesive resin layer 72 is adhered to the surface of the substrate structure SUB1, the adhesive resin layer 72 adhered thereto is fixed by heat. If the transfer substrate 70 is separated from the substrate structure SUB1 in this state in the element stripping-off step S6, there is a risk of generation of the fixed and remained adhesive resin layer 72 on the surface of the substrate structure SUB1.

However, the transfer substrate 70 according to the present disclosure includes the coating film 73 provided on the surface of the adhesive resin layer 72 and having the lower surface adhesiveness than that of the adhesive resin layer 72, and the adhesion of the adhesive resin layer 72 to the substrate structure SUB1 in the element compressing step S4 is suppressed. Thus, even if the laser LZ is emitted in the laser emitting step S5, the fixation of the adhesive resin layer 72 to the substrate structure SUB1 can be suppressed. Therefore, diffuse reflection of light and the like in the display apparatus DPS1 can be suppressed, and the performance of the display apparatus DPS1 can be improved.

The embodiments and the typical modification examples have been described above. However, the above-described techniques are applicable to various modification examples other than the exemplified modification examples. For example, the above-described modification examples may be combined.

In the scope of the idea of the present invention, various modification examples and alteration examples could have been easily anticipated by those who are skilled in the art, and it would be understood that these various modification examples and alteration examples are within the scope of the present invention. For example, the ones obtained by appropriate addition, removal, or design-change of the components to/from/into each of the above-described embodiments by those who are skilled in the art or obtained by addition, omitting, or condition-change of the step to/from/into each of the above-described embodiments are also within the scope of the present invention as long as they include the idea of the present invention.

For example, in the transfer substrate preparing step S2 of the above-described embodiments, the transfer substrate 70 including the coating film 73 provided on the surface of the adhesive resin layer 72 is prepared. However, the coating film 73 is not always prepared in the transfer substrate preparing step S2. That is, the coating film 73 only has to be provided on the surface of the adhesive resin layer 72 prior to the element compressing step S4. In other words, in the element compressing step S4, the transfer substrate 70 only has to include the coating film 73 as described above.

### <Statements>

Note that the present technique may employ the following configurations.

### (Statement 1)

A transfer substrate includes: a support substrate; an adhesive resin layer continuously provided on one surface of the support substrate and having a plurality of holding regions adhesively holding elements; and a coating film provided on a surface of the adhesive resin layer opposite to the support substrate to cover an outer region of the holding region of the adhesive resin layer and having lower surface adhesiveness than surface adhesiveness of the adhesive resin layer.

### (Statement 2)

In the transfer substrate according to the Statement 1, the coating film has an opening provided to surround a periphery of the holding region and positioned to face each of the plurality of holding regions.

### (Statement 3)

In the transfer substrate according to the Statement 2, the opening has an opening shape formed along a planar shape of the element held by the holding region.

### (Statement 4)

In the transfer substrate according to the Statement 2 or 3, a size of a gap between the opening and the holding region in plan view is 1 to 2.5 μm.

### (Statement 5)

In the transfer substrate according to any one of the Statements 1 to 4, a thickness of the coating film is smaller than a height of the element.

### (Statement 6)

In the transfer substrate according to any one of the Statements 1 to 4, a thickness of the coating film is larger than a height of the element.

### (Statement 7)

In the transfer substrate according to any one of the Statements 1 to 6, a thickness of the adhesive resin layer is larger than a height of the element.

### (Statement 8)

In the transfer substrate according to any one of the Statements 1 to 7, the coating film is a metallic thin film made of a metallic material.

### (Statement 9)

A method of manufacturing an electronic apparatus includes: a step (a) of preparing a transfer substrate according to any one of the Statements 1 to 8; a step (b) of adhesively holding the elements in the plurality of holding regions of the adhesive resin layer configuring the transfer substrate; a step (c) of preparing a circuit substrate including a plurality of arranged bump electrodes, compressing the transfer substrate adhesively holding the elements in the plurality of holding regions against the circuit substrate, and making contact of the plurality of bump electrodes with electrodes of the elements adhesively held by the plurality of holding regions, respectively; and a step (d) of bonding the bump electrodes and the electrodes of the elements by heat while the plurality of bump electrodes come into contact with the electrodes of the elements adhesively held by the plurality of holding regions, respectively.

### (Statement 10)

A method of manufacturing an electronic apparatus includes: a step (a) of preparing a transfer substrate including a support substrate and an adhesive resin layer continuously provided on one surface of the support substrate and having a plurality of holding regions adhesively holding elements; a step (b) of adhesively holding the elements in the plurality of holding regions of the adhesive resin layer configuring the transfer substrate; a step (c) of preparing a circuit substrate including a plurality of arranged bump electrodes, compressing the transfer substrate adhesively holding the elements against the circuit substrate, and making contact of the plurality of bump electrodes with electrodes of the elements held by the plurality of holding regions, respectively; and a step (d) of bonding the bump electrodes and the electrodes of the elements by heat while the plurality of bump electrodes come into contact with the electrodes of the elements adhesively held by the plurality of holding regions, respectively. In the step (c), the transfer substrate is compressed against the circuit substrate while an outer region of the holding region of the adhesive resin layer is covered with a coating film having lower surface adhesiveness than surface adhesiveness of the adhesive resin layer.

### (Statement 11)

In the method of manufacturing the electronic apparatus according to the Statement 10, the coating film has an opening provided to surround a periphery of the holding region and positioned to face each of the plurality of holding regions.

### (Statement 12)

In the method of manufacturing the electronic apparatus according to the Statement 11, the opening has an opening shape formed along a planar shape of the element held by the holding region.

### (Statement 13)

In the method of manufacturing the electronic apparatus according to the Statement 11 or 12, a size of a gap between the opening and the holding region in plan view is 1 to 2.5 μm.

### (Statement 14)

In the method of manufacturing the electronic apparatus according to any one of the Statements 10 to 13, a thickness of the coating film is smaller than a height of the element.

### (Statement 15)

In the method of manufacturing the electronic apparatus according to any one of the Statements 10 to 13, a thickness of the coating film is larger than a height of the element.

### (Statement 16)

In the method of manufacturing the electronic apparatus according to the Statement 15, the thickness of the coating film is larger than a total of a height of the element and a height of the bump electrode.

### (Statement 17)

In the method of manufacturing the electronic apparatus according to any one of the Statements 10 to 16, a thickness of the adhesive resin layer is larger than a height of the element.

### (Statement 18)

In the method of manufacturing the electronic apparatus according to any one of the Statements 10 to 17, the coating film is a metallic thin film made of a metallic material.

The present invention is applicable to a transfer substrate used for transferring an electronic component (element) and to a method of manufacturing an electronic apparatus on which an electronic component is mounted by use of the transfer substrate.

What is claimed is:

1. A transfer substrate comprising:
a support substrate;
an adhesive resin layer continuously provided on one surface of the support substrate and having a plurality of holding regions adhesively holding elements; and
a coating film provided on a surface of the adhesive resin layer opposite to the support substrate to cover an outer region of the holding region of the adhesive resin layer and having lower surface adhesiveness than surface adhesiveness of the adhesive resin layer.

2. The transfer substrate according to claim 1,
wherein the coating film has an opening provided to surround a periphery of the holding region and positioned to face each of the plurality of holding regions.

3. The transfer substrate according to claim 2,
wherein the opening has an opening shape formed along a planar shape of the element held by the holding region.

4. The transfer substrate according to claim 1,
wherein a thickness of the coating film is smaller than a height of the element.

5. A method of manufacturing an electronic apparatus comprising steps of:
(a) preparing a transfer substrate,
wherein the transfer substrate comprises
a support substrate;
an adhesive resin layer continuously provided on one surface of the support substrate and having a plurality of holding regions adhesively holding elements; and
a coating film provided on a surface of the adhesive resin layer opposite to the support substrate to cover an outer region of the holding region of the adhesive resin layer and having lower surface adhesiveness than surface adhesiveness of the adhesive resin layer;
(b) adhesively holding the elements in the plurality of holding regions of the adhesive resin layer configuring the transfer substrate;
(c) preparing a circuit substrate including a plurality of arranged bump electrodes, compressing the transfer substrate adhesively holding the elements in the plurality of holding regions against the circuit substrate, and making contact of the plurality of bump electrodes with electrodes of the elements adhesively held by the plurality of holding regions, respectively; and
(d) bonding the bump electrodes and the electrodes of the elements by heat while the plurality of bump electrodes come into contact with the electrodes of the elements adhesively held by the plurality of holding regions, respectively.

6. The method of manufacturing an electronic apparatus according to claim 5,
wherein the coating film has an opening provided to surround a periphery of the holding region and positioned to face each of the plurality of holding regions.

7. The method of manufacturing an electronic apparatus according to claim 6,
wherein the opening has an opening shape formed along a planar shape of the element held by the holding region.

8. The method of manufacturing an electronic apparatus according to claim 5,
wherein a thickness of the coating film is smaller than a height of the element.
